(19) United States
(12) Patent Application Publication
(10) Pub. No.: US 2025/0048560 A1
(43) Pub. Date: Feb. 6, 2025

(54) COATING AGENT AND METHOD FOR MANUFACTURING MODULE USING THE COATING AGENT

(71) Applicant: SEKISUI CHEMICAL CO., LTD., Osaka-fu (JP)

(72) Inventors: Satoru KUROZUMI, Kyoto-fu (JP); Masao INOUE, Kyoto-fu (JP)

(73) Assignee: SEKISUI CHEMICAL CO., LTD., Osaka-fu (JP)

(21) Appl. No.: 18/920,089

(22) Filed: Oct. 18, 2024

Related U.S. Application Data
(63) Continuation of application No. 17/431,322, filed on Aug. 16, 2021.

(30) Foreign Application Priority Data
Mar. 11, 2019 (JP) 2019-044156

(51) Int. Cl. H05K 3/28; H05K 1/18

(52) U.S. Cl. CPC H05K 3/284; H05K 1/181; H05K 2201/0212; H05K 2201/0254; H05K 2201/0269; H05K 2201/062

(57) ABSTRACT

An electronic component having thermal insulation properties and insulation resistance, which is capable of being used for modularization by injection molding or the like. The electronic component has a circuit board on which an electronic element is mounted and a coating layer for coating the surface of the circuit board, wherein the coating layer contains at least a thermoplastic resin and hollow particles; and the coating layer has a concentration gradient of hollow particles in the thickness direction such that the content of the hollow particles in the coating layer is lower on the face side in contact with the circuit board.

### BACKGROUND OF THE INVENTION

### Field of the Invention

The present invention relates to a coating agent, in particular a coating agent for protecting an electronic component from heat having various electron elements mounted on a circuit board and a method for manufacturing a module using the coating agent.

### Background Art

Conventionally, an electronic control unit (ECU) mounted on automobiles is generally consisted of a circuit board to which an electronic component such as a semi-conductor component is mounted and a housing for storing the circuit board. The electronic component is fixed by, for example, soldering the terminal of the electronic component to a wiring circuit pattern of the circuit board. Generally, a housing is consisted of a base which fixes the circuit board and a cover which is assembled on the base such that the circuit board is covered, as disclosed in Patent Document 1.

In recent years, there has been a need for down-sizing of such an automobile-mounted electronic control unit due to restriction of space. Along with such need, the device is required for down-sizing, and as like in Patent Document 2, there is disclosed a module obtained by installing a circuit board having various electron elements mounted on a board in a die for injection molding, and sealing and integrating the circuit board with a thermoplastic resin.

In order to deal with environmental problems, lead-free solder has been frequently employed in the recent years, and such lead-free solder has been known to develop whiskers over time. In the automobile field as above, there is also a trend of minimizing the electronic circuit along with the down-sizing of the circuit board, and a circuit board using the lead-free solder has a problem that the adjacent electronic elements cause short-circuit with each other or the solder with each other. To such problem, Patent Document 3, etc. proposes coating the solder part with hollow particles.

### PRIOR ART

### Patent Document

Patent Document 1: WO 2017/38343 A
Patent Document 2: JP2012-151296 A
Patent Document 3: JP 2013-131559 A

### SUMMARY OF THE INVENTION

The present inventors have made an attempt to reduce the space that is inevitably generated between the electronic component and the exterior covering by sealing the circuit board with a thermoplastic resin by means of in-mold molding instead of protecting the circuit board with the exterior covering, and found that there is a risk of causing problem in manufacturing that the solder part on the circuit board re-melts due to the heat from the melted resin and the die at the time of in-molding, causing connection failure with the solder and the substrate. Therefore, the present inventors have made an attempt to coat the solder part by applying a coating agent comprising hollow particles and a thermoplastic resin onto the surface of the circuit board as proposed in Patent Document 3; however, have found a new problem that although heat during in-mold molding can be suppressed from being transmitted to the electronic component by the coating layer, the volume resistivity of the coating layer decreases and insulation resistance of the electronic board is lowered.

Accordingly, the object of the present invention is to provide an electronic component having thermal insulation properties and insulation resistance, which can be suitably used for modularization by injection molding and the like.

Another object of the present invention is to provide a method for manufacturing the electronic component, a module using the electronic component, and a method for manufacturing the module.

### Means for Solving the Problem

In order to solve the above-mentioned problems, the present inventors have conducted intensive studies to find that hollow particles contained in the coating layer cause the reduction of volume resistivity. The present inventors have found that excellent thermal insulation properties and high volume resistivity can be achieved at the same time in the coating layer containing the hollow particles by providing a concentration gradient of the hollow particles in the thickness direction of the coating layer so that the content of the hollow particles on the surface side in contact with the circuit board is lower in the coating layer comprising the hollow particles, thereby completing the following invention. The gist of the present invention is as described in [1] to [13] below.

[1] An electronic component comprising a circuit board on which an electronic element is mounted and a coating layer for coating the surface of the circuit board, wherein
the coating layer comprises at least a thermoplastic resin and hollow particles; and
the coating layer has a concentration gradient of hollow particles in the thickness direction such that the content of the hollow particles in the coating layer is lower on the face side in contact with the circuit board.

[2] The electronic component according to [1], wherein
the coating layer comprises at least a first layer in which the content of the hollow particles is less than 1% by mass and a second layer in which the content of the hollow particles is 1% by mass or more.

[3] The electronic component according to [1] or [2], wherein
the coating layer further comprises a third layer in which the content of the hollow particles is 0% by mass or more.

[4] The electronic component according to [2] or [3], wherein the first layer is provided on the face side in contact with the circuit board.

[5] The electronic component according to any one of [1] to [4], wherein the hollow particles contain an acrylic resin.

[6] The electronic component of any one of [2] to [5], wherein the second layer has a thermal conductivity of less than 0.2 W/m·k.

[7] The electronic component according to any one of [2] to [6], wherein
the first layer has a volume resistivity of 3×10⁹ M Ω·cm or more.

[8] The electronic component according to any one of [1] to [7], wherein
the coating layer has a thickness of 50 to 500 μm.

[9]A method for manufacturing an electronic component of any one of [2] to [8], comprising the steps of:
applying a first layer forming composition to the surface of a circuit board on which an electronic element is mounted to form a first layer; and
applying a second layer forming composition to the surface of the first layer to form a second layer.

[10] The method according to [9], wherein
the coating is a dipping process.

[11] The method according to [9] or [10], wherein
the coating film is dried after the application of the first layer forming composition, and the first layer forming composition is repeatedly applied onto the coating film.

[12]A module comprising an electronic component according to any one of [1] to [8] and an outer package for covering the surface of the electronic component.

[13]A method for manufacturing a module according to [12], comprising the step of disposing the electronic component in a mold to perform injection molding, and forming an outer package so as to cover the surface of the electronic component.

### Effect of the Invention

According to the electronic component of the present invention, a coating layer provided on the surface of a circuit board on which an electronic element is mounted has a concentration gradient of hollow particles in the thickness direction such that the content of the hollow particles in the coating layer is lower on the face side in contact with the circuit board; therefore, a portion having a large content of the hollow particles in the coating layer exhibits an insulating effect and can suppress re-melting of a conductive adhesive member such as solder due to heat during injection molding or thermal deterioration of the board (stress breakage due to thermal expansion of a resin, etc.), and also a portion having a small content of the hollow particles in the coating layer exhibits an electrical insulating effect, thereby making an electronic component having a circuit board with excellent insulation resistance.

### BRIEF DESCRIPTION OF THE DRAWINGS

FIG. 1 is a schematic cross-sectional view of an electronic component according to one embodiment of the present invention.

FIG. 2 is a schematic cross-sectional view of an electronic component according to another embodiment of the present invention.

FIG. 3 is an enlarged schematic cross-sectional view of a coating layer portion of an electronic component according to one embodiment of the present invention.

FIG. 4A is an enlarged schematic cross-sectional view of a coating layer portion of an electronic component according to another embodiment of the present invention.

FIG. 4B is an enlarged schematic cross-sectional view of a coating layer portion of an electronic component according to another embodiment of the present invention.

FIG. 5A is an enlarged schematic cross-sectional view of a coating layer portion of an electronic component according to another embodiment of the present invention.

FIG. 5B is an enlarged schematic cross-sectional view of a coating layer portion of an electronic component according to another embodiment of the present invention.

FIG. 6 is a schematic cross-sectional view of an electronic component according to one embodiment of the present invention.

FIG. 7 is a flow chart of a method for manufacturing a module according to one embodiment of the present invention.

### EMBODIMENT FOR CARRYING OUT THE INVENTION

One example of a preferred embodiment of the present invention will be described with reference to the drawings. However, the embodiments described below are examples for describing the present invention, and the present invention shall not be limited to the embodiments described below in any way.

### [Electronic Component]

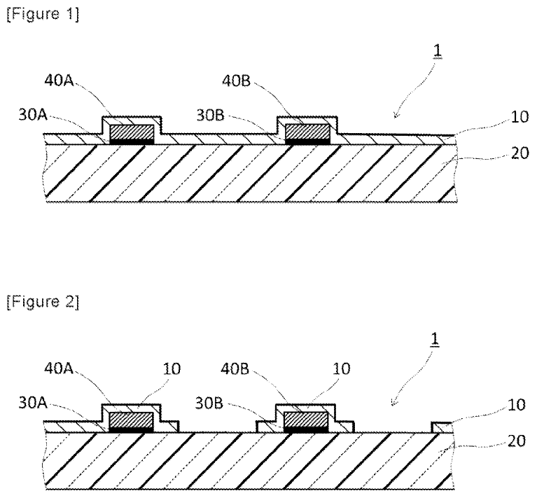

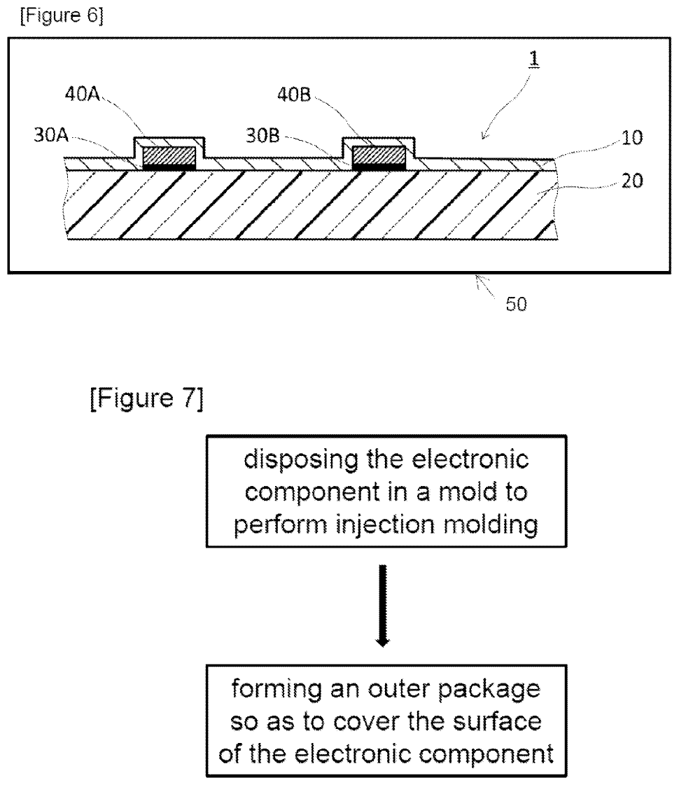

FIG. 1 is a schematic cross-sectional view of an electronic component according to one embodiment of the present invention. As shown in FIG. 1, electronic component 1 includes circuit board 20 on which electronic elements 40A, 40B are mounted via solders 30A, 30B, and a coating layer 10. The surface of the circuit board 20, including the electronic elements 40A, 40B, is coated with a coating layer 10. The coating layer may cover the entire circuit board, but as shown in FIG. 2, only the vicinity of the soldered electronic elements 40A, 40B, which are susceptible to heat and the like, may be coated with the coating layer 10. FIG. 6 shows an embodiment having an outer package 50 covering the surface of the electronic component 1.

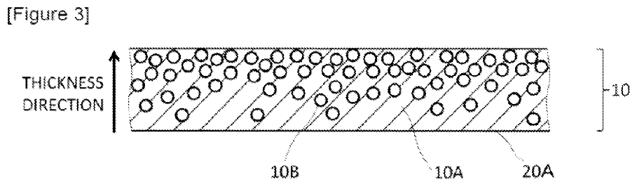

FIG. 3 is an enlarged schematic cross-sectional view of a coating layer portion of an electronic component of the present invention. As shown in FIG. 3, the coating layer 10 includes at least a thermoplastic resin 10A and hollow particles 10B. The coating layer 10 has a concentration gradient of hollow particles in the thickness direction so that the content of the hollow particles 10B in the coating layer 10 is lower on the side of face 20A in contact with the circuit board. The concentration gradient in the present invention means that there is a density gradient of the hollow particles in any part of the layer or between the layers.

In the present invention, the portion having a large content of hollow particles exhibits an insulating effect, and re-melting of a conductive adhesive member such as solder due to heat during injection molding and thermal deterioration of the board (stress fracture due to thermal expansion of a resin, etc.) can be suppressed. On the other hand, the portion having a small content of hollow particles in the coating layer exhibits an electrical insulating effect, and excellent dielectric breakdown strength can be maintained in the case of a module as described later. In other words, the problem that electrical insulating properties decrease due to the inclusion of hollow particles is solved by providing a portion having a small content of hollow particles in a coating layer, and both thermal insulation properties and electrical insulating properties are achieved.

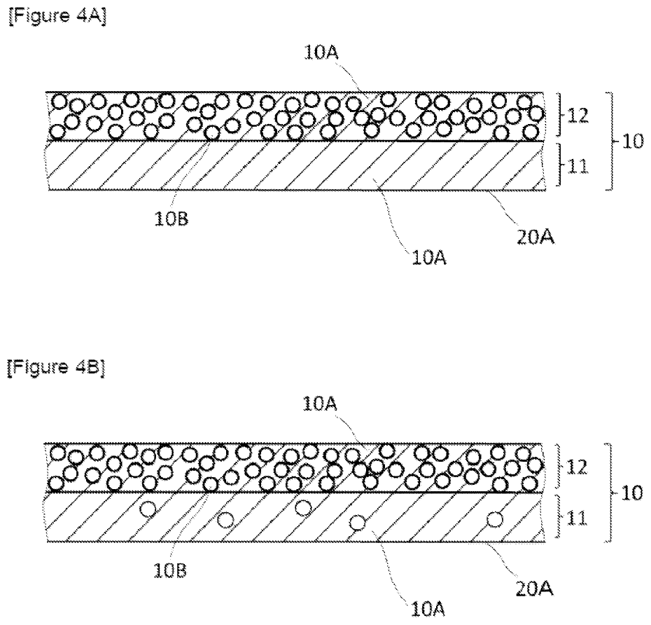

In the embodiment of the present invention, the coating layer 10 may be provided with a concentration gradient of the hollow particles so that the content of the hollow particles gradually changes in the thickness direction as shown in FIG. 3, but as shown in FIG. 4A, the coating layer 10 may have a two layer structure of a first layer 11 not containing the hollow particles 10B and a second layer 12 containing the hollow particles 10B. In the embodiment as shown in FIGS. 4A and 4B, it is preferable that the first layer 11 is provided on the side of surface 20A in contact with the circuit board from the viewpoint of achieving both thermal insulation and electrical insulation. Note that, the first layer 11 may contain hollow particles as shown in FIG. 4B, only that they are not contained substantially, and the content of the hollow particles may be less than 1% by mass. It is preferable that the second layer 12 contains at least 1% by mass or more of the hollow particles.

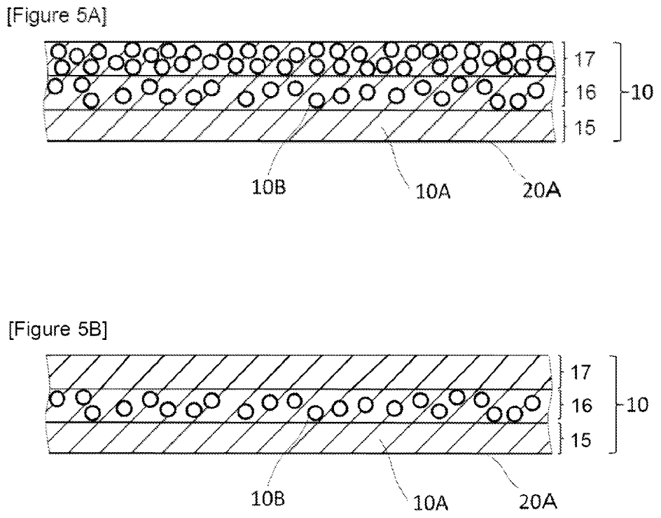

Further, in the embodiment of the present invention, the coating layer may be composed of a plurality of three or more layers, as shown in FIG. 5A, for example, a first layer 15 not containing hollow particles, a second layer 16 containing hollow particles, and a third layer 17 containing hollow particles. Also in this case, from the viewpoint of compatibility between thermal insulation and electrical insulation, the first layer 15 is preferably provided on the side of the surface 20A in contact with the circuit board. Further, the content of the hollow particles in the second layer 16 and the third layer 17 may be the same, but from the viewpoint of achieving both thermal insulation and electrical insulation, the content of the hollow particles in the third layer 17 is preferably larger than that in the second layer 16, which is shown in FIG. 5A. FIG. 5B further shows an embodiment where the third layer does not contain the hollow particles 10B.

Although not illustrated, when the coating layer has three or more layers, the layer structure may be that the first layer does not contain hollow particles, the second layer contains hollow particles, and the third layer does not contain hollow particles, in the present invention.

Hereinafter, a composition for forming a coating layer constituting an electronic component of the present invention will be described.

The coating layer constituting the electronic component described above can be formed by using a composition containing at least a thermoplastic resin and hollow particles and applying and drying onto the surface of a circuit board on which electronic elements are mounted.

### <Thermoplastic Resin>

Thermoplastic resins to be contained in the composition for forming a coating layer for use can be those conventionally known, examples thereof being synthetic resins and water-based emulsion resins. Examples of the synthetic resin include polyolefin-based resins, phenol resins, alkyd resins, aminoalkyd resins, urea resins, silicon resins, melamine urea resins, epoxy resins, polyurethane resins, vinyl acetate resins, acrylic resins, chlorinated rubber-based resins, vinyl chloride resins, and fluorine resins, and one of these resins can be used, or two or more in combination. Preferred to be used among these thermoplastic resins are polyolefin-based resins, in view of the adhesiveness between the circuit board and the hollow particles, and more preferred are polyolefin-based elastomers. Particular examples of the polyolefin-based elastomers include copolymers of propylene and α olefin, α olefin polymers, ethylene-propylene-based rubbers such as ethylene-propylene rubbers (EPM), ethylene-propylene-diene rubbers (EPDM), chloro sulfonated polyethylene (CSM), and the like. Examples of the water-based emulsion include silicon acryl emulsions, urethane emulsions, and acryl emulsions.

The composition for forming a coating layer according to the present invention preferably includes 5 to 40% by mass of a thermoplastic resin, and in view of shock protection of the electron elements such as a semi-conductor, the blending amount of the thermoplastic resin is 8 to 30% by mass and further preferably 10 to 20% by mass. Note that, the blending amount of the thermoplastic resin as used herein means the blending amount of the thermoplastic resin in terms of solid content.

### <Organic Solvent>

The composition for forming a coating layer may include an organic solvent. The organic solvent functions as a dispersion medium for dissolving or dispersing the above-described thermoplastic resin, the hollow particles, and other components to be described later. There is no limitation to the organic solvent used, as long as it possesses such function, and use can be made by appropriately selecting from conventionally known organic solvents such as ketone-, alcohol-, aromatic-based organic solvents upon taking into consideration the solubility, volatilization rate, dispersibility of the hollow particles, compatibility with other fillers and the dispersing agent. Particular examples include, acetone, methyl ethyl ketone, alkylcyclohexane, cyclohexene, ethylene glycol, propylene glycol, methyl alcohol, ethyl alcohol, isopropyl alcohol, butanol, benzene, toluene, xylene, ethyl acetate, butyl acetate and the like, among which cyclohexane having an alkyl group having 1 to 5 carbons is preferably used. These may be used alone or in combination of two or more.

When polyolefin-based resins are used as the thermoplastic resin, the organic solvent suitably used can be an aliphatic hydrocarbon having 1 to 12 carbons, in particular methylcyclohexane, in view of solubility.

The composition for forming a coating layer according to the present invention preferably includes 5 to 95% by mass of the organic solvent, and in view of achieving both of ensured flowability at the time of the applying step and simplicity in the drying step after applying, the blending amount of the organic solvent is 30 to 92% by mass and further preferably 60 to 90% by mass.

### <Hollow Particle>

The hollow particles included in the composition for forming a coating layer impart heat insulating properties to the coating. Such hollow particles may be either shingle-hole hollow particles or multi-hole hollow particles. Note that, the single-hole hollow particles mean particles having one hole inside the particles. The multi-hole hollow particles mean particles having a plurality of holes inside the particles. The plurality of holes in the multi-hole hollow particles may be present independently or connected.

The hollow particles are preferably having a hollowness of 40 to 95% by volume, and in view that the heat-insulation shape can be preserved after the organic solvent is volatilized, the hollowness is more preferably 40 to 70% by volume and further preferably 45 to 60% by volume. Note that, the hollowness in the present invention means the value measured by the following method.

In relation to the measured value (B) of the density of the hollow particles, the theoretical density of the material forming those hollow particles is determined as (A), and the hollowness (C) can be calculated from the following formula.

$$C ( \% ) = ( A - B ) / A \times 100$$

Since the hollow particles are preferably made into a coating in a uniformly dispersed state in the thermoplastic resin, the hollow particles preferably have a specific gravity of 5.0 or less and more preferably 0.1 to 1.5. Note that, the specific gravity of the hollow particles in the present invention means the density of the hollow particles (i.e. measured value (B)) based on the density of water (1.0 g/cm³).

Note that in the case of a composition in which a thermoplastic resin and hollow particles are dissolved or dispersed in an organic solvent and the specific gravity of the hollow particles is smaller than that of the thermoplastic resin, when a coating layer composition is applied to the surface of a circuit board to form a coating film, the concentration of the hollow particles increases in the vicinity of the surface of the coating film due to the difference in specific gravity between the thermoplastic resin and the hollow particles during the period from evaporation of the organic solvent to drying of the coating film, and as a result, as shown in FIG. 3, a concentration gradient of the hollow particles can be provided in the thickness direction of the coating layer such that the content of the hollow particles in the coating layer is lower on the surface side in contact with the circuit board.

The average particle diameter of the hollow particles is preferably 1 to 500 μm, more preferably 5 to 100 μm, and further preferably 10 to 70 μm, in view of suppressing slipping. Note that, the average particle diameter in the present invention means the average value (D50) of the particle size obtained by measuring the powder form hollow particles by means of laser diffraction scattering particle size distribution measuring method.

The hollow particles may be any of thermoplastic resin particles, thermosetting resin particles, organic hollow particles having glass shell (resin hollow particles), or inorganic hollow particles such as glass particles, ceramics particles, and the like, and in view of mechanical properties, suitable use is made to thermoplastic resin particles. Examples of the thermoplastic resins which can be used for the hollow particles include organic hollow particles having a shell of homopolymers of monomers having a styrene structure (styrene, parachloro styrene, α-methylstyrene, etc.), monomers having a (meth)acryloyl group (acrylic acid, methacrylic acid, (meth) acrylic ester (methyl acrylate, ethyl acrylate, n-propyl acrylate, n-butyl acrylate, lauryl acrylate, nitrile acrylate, 2-ethylhexyl acrylate, methyl methacrylate, ethyl methacrylate, n-propyl methacrylate, lauryl methacrylate, 2-ethylhexyl methacrylate, etc.), monomers of vinyl acetate, vinyl ether (for example, vinyl methyl ether, vinyl isobutyl ether, etc.), vinyl ketone (vinyl methyl ketone, vinyl ethyl ketone, vinyl isopropenyl ketone, etc.), olefin (for example, ethylene, propylene, butadiene, etc.), or copolymers formed by combining two or more of these monomers.

Examples of the hollow particles also include organic hollow particles having a shell made of non-vinyl resins (epoxy resin, polyester resin, polyurethane resin, polyamide resin, polyamide resin, cellulose resin, polyether resin, modified rosin, etc.), a mixture of these resins and the vinyl resin, or a graft polymer obtained by polymerizing a vinyl monomer in the presence of these resins.

Preferably used among the above-described resins are polyacrylonitrile- or acryl-based resins, in view of heat resistance.

The hollow particles may be either of expandable type or non-expandable type. Note that, the hollow particles of expandable type mean the particles in which the volume of the particles (or the holes inside) increases by external stimulation such as heat.

The hollow particles as above may be of one commercially available, examples thereof being inorganic hollow particles such as Advancel EM, HB (both manufactured by Sekisui Chemical Co., Ltd.), ExpanCel U, E (both manufactured by Nippon Ferrite Co., Ltd.), Matsumoto Microsphere F, F-E (both manufactured by MATSUMOTO YUSHI-SEIYAKU CO., LTD.), and Silinax (manufactured by Nittetsu Mining Co., Ltd.), E-spheres (manufactured by Taiyo Cement Corporation), hard light (manufactured by Showa Chemical Co., Ltd.), cenolite, marlite, glass balloon (both manufactured by TOMOE ENGINEERING CO., LTD.), and the like.

The content of the hollow particles contained in the composition for forming a coating layer is preferably 1 to 10% by mass, more preferably 3 to 8% by mass in terms of solid content. As shown in FIGS. 4 and 5, when the coating layer is composed of a plurality of layers, the content of the hollow particles in the composition for forming each coating layer may be adjusted. In particular, it is preferable that the composition for forming the first layer provided on the face side in contact with the circuit board contains no hollow particles.

The composition for forming a coating layer may contain other components in addition to the above components. For example, an aliphatic amide compound may be contained. The inclusion of an aliphatic amide compound improves the dispersion stability of the thermoplastic resin and the hollow particles in the composition for forming a coating layer, and when the coating layer is formed by applying the composition for forming a coating layer to the surface of a circuit board, the thermoplastic resin and the hollow particles are uniformly dispersed in the coating layer (coating film), and as a result, the coating layer is considered to have uniform thermal insulation properties. The aliphatic amide compound is a compound having an —NH—CO— bond in a molecule, and examples thereof include a reaction product of a fatty acid and an aliphatic amine and/or an alicyclic amine, an oligomer thereof, and the like. Since a compound having an amide bond forms a mesh-like network structure in which a hydrogen bond is involved, it is considered that the formation of the network structure is related to the uniform dispersibility of the hollow particles.

The aliphatic amide compound is preferably one having thixotropy. By using an aliphatic amide compound having thixotropy, hollow particles tend to be retained for a long time in a state of being uniformly dispersed.

The aliphatic amide compound which can be suitably used in the composition for forming a coating layer preferably has a fatty acid polyamide structure, and the fatty acid has a long-chain alkyl group having 8 to 30 carbon atoms. The long-chain alkyl group may be either linear or branched. In addition, the long-chain alkyl group may be repeatedly connected to the long chain by a carbon-carbon bond. Specific examples include saturated fatty acid monoamide such as lauric acid amide and stearic acid amide, unsaturated fatty acid monoamide such as oleic acid amide, substituted amide such as N-lauryl lauric acid amide and N-stearyl stearic acid amide, methylol amide such as methylol stearic acid amide, fatty acid such as methylene bisstearic acid amide, ethylene bislauric acid amide, ethylene bishydroxy stearic acid amide, unsaturated fatty acid bisamide such as methylene bis oleic acid amide, aromatic bisamide such as m-xylylene bisstearic acid amide, ethylene oxide adducts of fatty acid amide, fatty acid ester amide, fatty acid ethanol amide, and substituted urea such as N-butyl-N′-stearyl urea, and the like, and these can be used alone or two or more in combination. Among these, saturated fatty acid monoamide is more preferable from the viewpoint of improving dispersibility of the hollow particles in the composition by thixotropic action.

For the above-mentioned aliphatic amide compounds, use may be made to those commercially available, and examples thereof include DISPARLON 6900-20X, DISPARLON 6900-10X, DISPARLON A603-20X, DISPARLON A603-10X, DISPARLON A670-20M, DISPARLON 6810-20X, DISPARLON 6850-20X, DISPARLON 6820-20M, DISPARLON 6820-10M, DISPARLON FS-6010, DISPARLON PFA-131, DISPARLON PFA-231 (all manufactured by Kusumoto Kasei Co., Ltd.), Flownon RCM-210 (manufactured by Kyoeisha Chemical Co., Ltd.), BYK-405 (manufactured by BYK Chemie Japan), and the like.

The composition for forming a coating layer preferably contains 0.001 to 10% by mass of an aliphatic amide compound, and from the viewpoint of uniform dispersion of the hollow particles, the amount of the aliphatic amide compound blended is more preferably 0.05 to 7% by mass, further preferably 0.1 to 1% by mass. Here, the content of the aliphatic amide compound means a ratio of the aliphatic amide compound contained with respect to the total sum of the thermoplastic resin (A) and the organic solvent (B).

### <Circuit Board>

The circuit board is preferably, but not limited to, a circuit board on which electronic elements such as semiconductor elements, resistor chips, capacitors, and external connection terminals are mounted, particularly a circuit board constituting various electronic control units (ECU). An electronic control unit can be manufactured by mounting various electronic elements such as semiconductor elements, resistor chips, capacitors, and external connection terminals on a circuit board such as a printed wiring board, and modularizing an electronic component in which the circuit board and each element are electrically connected by a conductive bonding member such as solder. The various electronic control units are preferably electronic control units for aircraft and automobiles, and more preferably electronic control units for sensors.

Various electronic elements such as a semiconductor element, a resistor chip, a capacitor, and a connection terminal to the outside are mounted on the circuit board. In addition, the circuit board and the electronic elements are electrically connected by a conductive adhesive member. Examples of the conductive adhesion member may be synthetic resins including a conductive filler, and solder, and solder is preferably used. Solder may preferably contain tin (Sn), and examples thereof include Sn—Pb-based alloy, Sn—Ag—Cu-based alloy, Sn—Zn—Bi-based alloy, Sn—Zn—Al-based alloy, and the like, and in view of regulations relating to environment, preference is made to the use of the so-called lead-free solder such as Sn—Ag—Cu-based alloy, Sn—Zn—Bi-based alloy, and Sn—Zn—Al-based alloy.

Examples of the resins containing a conductive filler include those that contain conductive fillers such as gold, silver, copper, nickel, aluminum in thermo-setting resins such as epoxy-based resins and phenol-based resins and thermoplastic resins such as polyester-based resins, polyolefin-based resins, polyurethane-based resins, and polycarbonate-based resins.

In view of workability when electrically connecting the wiring substrate and various elements, the conductive adhesion member has a melting point of generally 250° C. or lower, preferably 220° C. or lower, more preferably 200° C. or lower, and further preferably 190° C. or lower. Note that, when a thermosetting resin and the like is used as a resin containing a conductive filler and when the thermosetting resin cannot be measured for its melting point, the melting point may be replaced by the heat-resistant temperature.

### [Method for Manufacturing Electronic Component]

The electronic component according to the present invention can be formed by applying and drying the composition for forming a coating layer described above on the surface of the circuit board on which the electronic element is mounted. The method is generally shown in the flowchart provided in FIG. 7. Particularly, in the case of forming a coating layer composed of a plurality of layers as shown in FIGS. 4 and 5, a coating layer composed of a plurality of layers can be formed by first applying a composition for forming a first layer containing no hollow particles on the surface of the circuit board on which the electronic element is mounted to form a first layer, and applying a composition for forming a second layer containing hollow particles on the surface of the first layer to form a second layer.

In the application of the composition for forming a coating layer, the coating agent is applied on the electronic component so that at least the conductive adhesive member portion of the electronic component is covered. From the viewpoint of protecting various electronic elements from heat, it is preferable to apply the composition for forming a coating layer so that not only the conductive adhesive member portion but also the entire circuit board on which various electronic elements are mounted is covered. The composition for forming a coating layer can be applied to the surface of the circuit board by a conventionally known method such as a screen printing method, a bar coater, a blade coater, or dipping, but in the present invention, it is preferable to perform the dipping process.

After the coating layer forming composition is applied, the organic solvent can be removed by drying to form a coating layer. The drying may be performed at normal temperature or by using a hot air dryer or the like.

Further, the coating and drying steps may be repeated in order to adjust the thickness of the coating layer. In particular, the coating film is dried after application of the composition for forming a first layer, and repeatedly applying the first layer forming composition on the coating film, and drying the coating film to make the first layer thicker than the second layer.

The thickness of the coating layer formed as described above is preferably 50 to 500 μm, more preferably 100 to 300 μm. In the embodiment of the present invention, as shown in FIG. 4, when the coating layer is composed of two layers of a first layer and a second layer, the ratio of the thickness of the first layer to the thickness of the second layer is preferably 1:1 to 3:1, more preferably 1.5:1 to 2.5:1.

In an embodiment of the present invention, as shown in FIG. 4, when the coating layer is composed of two layers of a first layer and a second layer, the first layer does not contain hollow particles and therefore has a volume resistivity of 3×10⁹ MΩ·cm or more. Accordingly, an electronic component having excellent insulation resistance can be obtained. The volume resistivity means a value measured in accordance with JIS K6911.

Since the second layer contains hollow particles, it has a thermal conductivity of less than 0.2 W/m·k. Therefore, it is possible to suppress re-melting of a conductive adhesive member such as solder due to heat during injection molding and thermal deterioration of the substrate (stress fracture due to thermal expansion of the resin, etc.). When it is assumed that the melting point of the solder is 217° C. and that the module is manufactured by injection molding of polybutylene terephthalate at a mold temperature of 240° C., the thermal conductivity necessary to suppress heating above the melting point during injection molding was calculated by simulation and found to be 0.2 W/m·K or less.

In addition, when the coating layer has a laminated structure of the first layer containing no hollow particles and the second layer containing hollow particles, as described above, the dielectric breakdown strength is unexpectedly improved.

### <Module>

The electronic component of the present invention may be housed and integrated in an outer package in order to protect an electronic component and made into a module. In recent years, there has been a demand for smaller modules, and instead of housing the electronic component in the outer package, the electronic component itself is sealed with a thermoplastic resin to form an integrated module. Such modules are produced by injection molding (in-mold molding) in which the electronic component is placed in a mold. In this case, the heat of the molten thermoplastic resin is transmitted to the electronic component, causing the conductive adhesive member such as solder to re-melt, and the electronic component may be broken by partial re-melting of the solder or thermal expansion of the resin. With the electronic component of the present invention, such heat from the outside can be shielded, and the breakage of the electronic component can be suppressed. In addition, since the module has a high volume resistivity, it is possible to provide a module having a circuit board having excellent insulating properties.

A module can be manufactured by covering electronic components, sensors, connecting terminals to the outside, and the like with a sealing material, but in the present invention, the module can be manufactured by arranging electronic components, sensors, connecting terminals to the outside, and the like within a mold, performing injection molding, and forming a thermoplastic resin outer package so as to cover the surface of the electronic components. The module may have a part of a circuit board, a sensor, a cable, or the like which is not covered with a sealing material. Further, by performing the so-called in-mold formation, it is possible to manufacture a module having a desired shape in which electronic components are sealed and integrated with a sealing material made of thermoplastic resin.

There is no limitation for the sealing material, as long as the resin is capable for injection molding, examples thereof being polyacetal, polyamide, polycarbonate, polybutylene terephthalate, polyethylene terephthalate, polyphenylene sulfide, polyacryl resin, ABS resin, and the like, and in view of molding and mechanical properties, preferred for use is polybutylene terephthalate.

When polybutylene terephthalate is used as the sealing material, there is a risk that the conductive adhesion member may be re-melted because the temperature at the time of injection-molding is about 230 to 270° C. In the present invention, less heat is transmitted to the electronic component by forming a coating on the surface of the electronic component, and as a result, it is possible to suppress the electronic component from being damaged due to re-melting of the conductive adhesion member or thermal expansion of the resin as described above.

### EXAMPLES

Hereinafter, the present invention shall be described in more detail with reference to the Examples; however, the present invention shall not be limited by those Examples.

### Example 1

The following Coating Compositions 1 and 2 were prepared as a coating layer forming composition.

### <Coating Composition 1>

As Coating Composition 1, a mixture of a thermoplastic resin and an organic solvent (Humiseal 1B51NSLU-40 (polyolefin elastomer 14 wt %, methylcyclohexane 86 wt %) manufactured by Air Brown Co., Ltd.) was prepared.

### <Coating Composition 2>

3 parts by mass of a mixture of a thermoplastic resin and an organic solvent (hollow particles (Advancel HB2051 (manufactured by Sekisui Chemical Co., Ltd., material: acrylonitrile, specific gravity: 0.4 g/cm³, hollow rate: 50%, average particle size: 20 μm) based on 100 parts by mass of Humiseal 1B51NSLU-40 manufactured by Air Brown Co., Ltd.) and 0.6 parts by mass of an aliphatic amide compound were added and sufficiently stirred to prepare Coating Composition 2.

A dipping step was repeated twice in which a polyimide film was dipped in the Coating Composition 1 described above, pulled up, and dried in air at 60° C. for 30 minutes to form a first layer on the surface of the polyimide film. Next, a dipping step was performed for once in which the polyimide film on which the first layer was formed was dipped in the Coating Composition 2, pulled up, and dried in air at 60° C. for 30 minutes to form a second layer.

In the polyimide film having the coating layer formed as described above, the total thickness of the first layer and the second layer was 307 μm. In addition, the ratio of the thickness of the first layer to that of the second layer was about 2:1.

The volume resistivity of the polyimide film having the coating layer formed thereon was measured in accordance with JIS-K 6911 using an ULTRA HIGH RESISTANCE METER R8340 manufactured by ADC.

In addition, the dielectric breakdown strength of the polyimide film having the coating layer formed thereon was measured in accordance with JIS C 2110 1:2016 by using a withstand voltage testing device manufactured by Kojima Electric Works. The evaluation results were as shown in Table 1 below.

### Comparative Example 1

The Coating Composition 1 was applied to a polyimide film using a bar coater and dried to evaporate the organic solvent, and as a result, only a first layer was formed. The thickness of the coating film was 300 μm. In addition to the same evaluation as in Example 1, the thermal conductivity of the resulting coating layer was measured by a non-steady fine wire heating method. The results were as shown in Table 1.

### Comparative Example 2

The Coating Composition 2 was applied to a polyimide film using a bar coater and dried to evaporate the organic solvent, and as a result, only a second layer was formed. The thickness of the coating film was 300 μm. In addition to the same evaluation as in Example 1, the thermal conductivity of the resulting coating layer was measured by a non-steady fine wire heating method. The results were as shown in Table 1.

TABLE 1

| | | Comparative | Comparative |
|---|---|---|---|
| | Example 1 | Example 1 | Example 2 |
| Thickness of First layer | 205 | 300 | — |
| (μm) | | | |
| Thickness of Second layer | 102 | — | 300 |
| (μm) | | | |
| Volume resistivity | 1.1 × 10¹⁰ | 3.8 × 10¹⁰ | 2.1 × 10⁹ |
| (MΩ · cm) | | | |
| Dielectric breakdown strength | 48.2 | 45.6 | 34.1 |
| (kVmm) | | | |
| Thermal conductivity | (0.2)^{*1} | 0.3 | 0.1 |
| (W/m · K) | | | |

When the thermal conductivity necessary to suppress the solder from being heated above the melting point during injection molding is calculated by simulation on the assumption that the melting point of solder is 217° C. and that injection molding of polybutylene terephthalate on the board is carried out at a mold temperature of 240° C., it is found that if the thermal conductivity is 0.2 W/m·K or less, re-melting of solder can be suppressed, and therefore the problem of the present invention can be achieved if the thermal conductivity is 0.2 W/m·K or less.

As is clear from the evaluation results in Table 1, the polyimide film (Comparative Example 2) provided with only a coating layer containing hollow particles has excellent thermal insulation properties, but the volume resistivity is one digit lower than that of the polyimide film (Comparative Example 1) provided with only a coating layer containing no hollow particles, and the dielectric breakdown strength is also inferior.

On the other hand, in the polyimide film (Example 1) provided with the first layer and the second layer, since the coating layer has a concentration gradient of hollow particles in the thickness direction so that the content of the hollow particles in the coating layer is lower on the surface side in contact with the polyimide film, both thermal insulation properties and volume resistivity are excellent, and an effect has been found that dielectric breakdown strength improves by lamination.

Although the dielectric breakdown strength of air is generally lower than that of the resin for semiconductor coating, it is considered that the formation of a layer containing hollow particles on the surface disperses and homogenizes the current in the surface layer, and as a result, the dielectric breakdown strength is improved more than that in a single layer.

1. A method for manufacturing an electronic module having an electronic component, a coating layer, and an outer package for covering the surface of the electronic component, comprising:
the step of disposing the electronic component in a mold to perform injection molding, and forming the outer package so as to cover the surface of the electronic component,
wherein the electronic component comprises a conductive adhesive member portion and a circuit board on which an electronic element is mounted,
wherein the coating layer coats a surface of the conductive adhesive member portion,
wherein the outer package comprises a first thermoplastic resin and covers a surface of the electronic components,
wherein the coating layer comprises at least a second thermoplastic resin and hollow particles,
wherein the coating layer has a concentration gradient of hollow particles in the thickness direction such that the content of the hollow particles in the coating layer is lower on the face side in contact with the circuit board, and
wherein the hollow particles are either single-hole hollow particles or multi-hole hollow particles.

2. The method for manufacturing an electronic module to claim 1, wherein
the coating layer comprises at least a first layer in which the content of the hollow particles is less than 1% by mass and a second layer in which the content of the hollow particles is 1% by mass or more.

3. The method for manufacturing an electronic module to claim 1, wherein
the coating layer further comprises a third layer in which the content of the hollow particles is 0% by mass or more.

4. The method for manufacturing an electronic module to claim 2, wherein
the first layer is provided on the face side in contact with the circuit board.

5. The method for manufacturing an electronic module to claim 1, wherein
the hollow particles contain an acrylic resin.

6. The method for manufacturing an electronic module to claim 2, wherein
the second layer has a thermal conductivity of less than 0.2 W/m·k.

7. The method for manufacturing an electronic module to claim 2, wherein
the first layer has a volume resistivity of 3×109M Ω·cm or more.

8. The method for manufacturing an electronic module to claim 1, wherein
the coating layer has a thickness of 50 to 500 μm.
